(19) United States
(12) Patent Application Publication
(10) Pub. No.: US 2003/0202372 A1
(43) Pub. Date: Oct. 30, 2003

(54) Semiconductor memory module

(75) Inventors: Yasuhiro Kashiwazaki, Hyogo (JP); Yoshio Fudeyasu, Hyogo (JP); Tatsuji Kobayashi, Hyogo (JP)

Correspondence Address: McDERMOTT, WILL & EMERY, 600 13th Street, N.W., Washington, DC, 20005-3096, US

(73) Assignees: Mitsubishi Denki Kabushiki Kaisha; Mitsubishi Electric Engineering Company Limited

(21) Appl. No.: 10/274,919

(22) Filed: Oct. 22, 2002

(30) Foreign Application Priority Data
Apr. 24, 2002 (JP) 2002-122630 (P)

(51) Int. Cl. G11C 5/02

(52) U.S. Cl. 365/51; 365/63

(57) ABSTRACT

A good chip for repair is provided only in a position on the rear surface of a module substrate corresponding to the position of a bare chip that has been detected as being defective. In addition, the entirety of the rear surface of the module substrate is integrally molded regardless of whether or not a good chip is mounted. Thereby, a semiconductor memory module is formed so as to be in a form wherein gaps do not easily occur between a plurality of semiconductor memory modules when the semiconductor memory modules are packed in a box for transport of the semiconductor memory modules. As a result, damage can be prevented from occurring in a semiconductor module wherein good chips for repair are mounted at the time of transport in packaging.

### BACKGROUND OF THE INVENTION

1. Field of the Invention

The present invention relates to a semiconductor memory module wherein memory chips are mounted on a module substrate.

2. Description of the Background Art

A semiconductor memory device is, in many cases, utilized in a personal computer, a workstation or the like. In addition, in recent years the speed, degree of compactness and number of functions of personal computers have increased and therefore, semiconductor memory devices have been required to further increase their memory capacity. In addition, the market has been expanded so that a large number of low-cost memory devices are used for the semiconductor memory device. Therefore, further increase in the capacity of, and further reduction in costs of, semiconductor memory devices have become required.

The number of DRAMs (Dynamic Random Access Memory), from among the above-described semiconductor memory devices, utilized in personal computers or the like, has increased because it is advantageous from the point of view of cost per bit unit. Cost per bit unit can be reduced by increasing the diameter of wafers even in the case that the capacity is increased and therefore, DRAMs are frequently utilized.

In a DRAM, however, cost of development, cost for high level institutions and the like have greatly increased together with the increase in the testing period of time and test costs accompanying the increase in capacity as well as the enhancement of microscopic processing technology so that whether or not those costs can be reduced has become a problem.

The bit configuration for the input to or output from a DRAM is conventionally 4 bits, 8 bits or 16 bits. Therefore, the variety in types of bit numbers is small. Accordingly, one module formed of a plurality of DRAMs is generally used. Thus, a semiconductor memory device such as a DRAM is, in many cases, utilized in a module condition.

FIGS. 21 and 22 show an example of a conventional semiconductor memory module. The conventional semiconductor memory module has a structure, wherein single chips 117, in which bare chips 101, mounting islands 104, bonding wires 105 and lead frames 110 are molded into mold resin 108, are mounted on a module substrate 102 such as an SOP (Small Outline Package) or a TSOP (Thin Small Outline Package) corresponding to a surface mounting technology wherein parts can be mounted on both sides of a printed circuit board. Here, in the present specification, a single chip indicates a chip wherein a single bare chip is sealed in a mold.

In addition, development has progressed of a memory package having a basic tendency toward miniaturization and thinning together with enhancement of performance and of functions of a memory chip. Then, though an insertion system was adopted for a memory package, in recent years the forms of packages have greatly changed such that a surface mounting system has been adopted.

At present, the surface mounting system has become the main trend in place of the insertion system and further miniaturization and lightening of packaging are strongly required. Up to the present, simplification of design and increase in reliability, as well as reduction in cost, have been achieved by utilizing a semiconductor memory module.

In addition, in a conventional manufacturing process of a semiconductor memory module, in the case that a defective chip is discovered in a module test after the manufacture of a semiconductor memory module, testing and replacement of such a defective chip are carried out until such defect has been removed.

As described above, there is a problem with the conventional semiconductor memory module wherein a plurality of single memory chip ICs (Integration Circuits) in the form of packaged single chips 117 are mounted on module substrate 102, as shown in FIG. 21, and therefore, the mounting area of the single memory chip ICs becomes large.

With respect to the above described problem, the present inventors examined the case wherein a plurality of bare chips provided on a module substrate were integrally molded, thereby high density mounting on a module substrate was achieved.

In addition, there is a problem wherein a great amount of time and effort are required for the replacement of a memory chip that has been detected as being defective according to the conventional manufacturing process of a semiconductor memory module. Furthermore, though there is a memory module in the form of a COB (Chip On Board) as a semiconductor memory module with which high density mounting can easily be carried out, there is a problem wherein a bare chip that has been detected as being defective cannot be repaired after bare chips have been sealed in a mold according to the conventional module in the form of a COB.

With respect to the above described problem, the present inventors examined a case wherein bare chips other than the bare chips that have become defective from among the plurality of bare chips are effectively utilized by newly mounting a nondefective chip (hereinafter, refer to as a good chip) even in the case that a chip defect is detected after the chips have been molded into mold resin.

As described above, in the case that a semiconductor memory module is repaired by mounting a good chip on a module substrate, however, the external forms, respectively, of a plurality of semiconductor memory modules become irregular as good chips are mounted on the module substrates only in positions corresponding to the bare chips that have been detected as being defective. That is to say, bare chips that become defective differ for every semiconductor memory module and therefore, the positions on the module substrate on which good chips are mounted differ for every semiconductor memory module.

Therefore, in the case that a plurality of semiconductor memory modules is transported, it becomes difficult to pack the plurality of semiconductor memory modules in a box for transportation in a well-arranged manner. That is to say, gaps occur among the semiconductor memory modules in a box for packing the semiconductor memory modules. As a result, the semiconductor memory modules collide with each other in the box during the transportation of the semiconductor memory modules. Thereby, the semiconductor memory modules are damaged.

### SUMMARY OF THE INVENTION

An object of the present invention is to provide a semiconductor memory module, that is a semiconductor module on which a good chip for repair is mounted, wherein damage is prevented from occurring at the time of transport in packaging.

In addition, in the semiconductor memory module examined by the present inventors described above wherein a plurality of bare chips provided on a module substrate are integrally molded, the memory capacity of the semiconductor memory module cannot be changed, increased or recovered.

Another object of the present invention is to provide a semiconductor memory module wherein the memory capacity of the semiconductor memory module can be changed, increased or recovered after the plurality of bare chips are molded into resin.

A semiconductor memory module according to the first aspect of the present invention is provided with a module substrate, a plurality of bare chips mounted on the main surface of the module substrate, one mold resin for integrally covering the plurality of bare chips together with the main surface of the module substrate, a plurality of good chip mounting regions that are regions on the main surface of the module substrate wherein one or plural good chips that function in place of one or plural bare chips that have been detected as being defective can be mounted in the case that any one or plural bare chips from among the plurality of bare chips have been detected as being defective, and a other mold resin for integrally covering, in the case that all of the good chips that can be mounted or the plurality of good chip mounting regions are supposed to be mounted regardless of whether or not one or plural good chips are mounted on the plurality of good chip mounting regions, the entirety of the plurality of good chip mounting regions together with the entirety of the supposed good chips.

According to the above-described configuration, the other mold resin is provided and therefore, a semiconductor memory module can be obtained in a form wherein gaps do not easily occur between a plurality of semiconductor memory modules when the semiconductor memory modules are packed in a box for transport of the semiconductor memory modules regardless of whether or not a good chip is mounted in the plurality of good chip mounting regions. Therefore, damage can be prevented from occurring in the semiconductor memory modules when the semiconductor memory modules are packed in a box and are transported.

In the semiconductor memory module of the first aspect of the present invention, one dummy chip that has approximately the same form and same size as that of one bare chip and that does not function as a good chip may be mounted in one region from among the plurality of good chip mounting regions.

According to the above-described configuration, the external form of the other mold resin can be made to have a structure wherein gaps do not easily occur between a plurality of semiconductor memory modules at the time when the semiconductor memory modules are packed in a box and are transported.

A semiconductor memory module of the second aspect of the present invention is provided with a module substrate, a plurality of bare chips mounted on the main surface of the module substrate and including one or plural defective bare chips that do not function properly, a mold resin for integrally covering the plurality of bare chips together with the main surface of the module substrate, and one or plural memory chips mounted on the main surface of the module substrate outside of the mold resin that function independently of the plurality of bare chips.

According to the above described configuration, bare chips that are not defective can be effectively utilized by using one or plural memory chips that function independently of the plurality of bare chips in the case that a bare chip (bare chips) is (are) detected as being defective from among the plurality of bare chips after the process of integrally covering the plurality of bare chips with a mold resin.

A semiconductor memory module of the third aspect of the present invention is provided with a module substrate, a plurality of bare chips mounted on the main surface of the module substrate, a mold resin for integrally covering the plurality of bare chips together with the main surface of the module substrate and, one or plural memory chips mounted on the main surface of the module substrate that function independently of the plurality of bare chips, wherein the function of at least one memory chip from among one or plural memory chips is disabled.

According to the above described configuration, the memory capacity of a semiconductor memory module can be changed according to the results of tests to determine whether or not memory chips are defective.

Here, it is possible to combine the characteristics of the semiconductor memory modules of the above described first to third aspects depending on conditions.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a condition wherein a plurality of bare chips mounted on a module substrate are integrally molded into a mold resin in a semiconductor memory module of a first embodiment;

FIG. 2 is a view for describing bare chips mounted on the module substrate of the first embodiment;

FIG. 3 is a view for describing a cross sectional structure of a bare chip and a good chip (single chip) mounted on the module substrate of the first embodiment;

FIG. 4 is a view for describing wherein one of bare chips mounted on the module substrate of the first embodiment becomes defective;

FIG. 5 is a view for describing that a semiconductor memory module is repaired by utilizing a good chip mounted on the rear surface of the module substrate of the first embodiment;

FIG. 6 is a diagram for describing a configuration of a module substrate of the first embodiment before repair;

FIG. 7 is a diagram for describing a configuration of a module substrate of the first embodiment after repair;

FIG. 8 is a diagram for describing an inside configuration of a semiconductor memory device (bare chip or good chip) of the first embodiment;

FIG. 9 is a view for describing the front surface of a repaired semiconductor memory module of the first embodiment;

FIG. 10 is a view for describing the rear surface of a repaired semiconductor memory module of the first embodiment;

FIG. 11 is a view for describing a condition wherein a mold resin is applied so as to cover the entirety of the main surface of a module substrate including not only good chips (bare chips) on the rear surface but also other regions of a repaired semiconductor memory module of the first embodiment;

FIG. 12 is a cross sectional view taken along a line XII-XII of FIG. 11;

FIG. 13 is a view showing a condition wherein a mold resin is applied so as to cover not only good chips (bare chips) but also dummy chips on the rear surface of a repaired semiconductor memory module of the first embodiment;

FIG. 14 is a cross sectional view taken along a line XIV-XIV of FIG. 13;

FIG. 15 is a view for describing a cross sectional structure of a bare chip and a good chip (single chip) mounted on a module substrate of second and third embodiments;

FIG. 16 is a diagram for describing a configuration of a semiconductor memory module of the second and third embodiments before repair;

FIG. 17 is a diagram for describing a configuration of a semiconductor memory module of the second and third embodiments after repair;

FIG. 18 is a view for describing a configuration of the front surface of the semiconductor memory module of the second and third embodiments after repair;

FIG. 19 is a view for describing a configuration of the rear surface of the semiconductor memory module of the second and third embodiments after repair (after bare chips are mounted as good chips);

FIG. 20 is a view for describing a cross section taken along a line XX-XX of FIG. 19;

FIG. 21 is a view seen from above for describing a configuration of a semiconductor memory module according to a prior art; and

FIG. 22 is a view for describing a cross sectional structure of the semiconductor memory module according to the prior art.

### DESCRIPTION OF THE PREFERRED EMBODIMENTS

(First Embodiment)

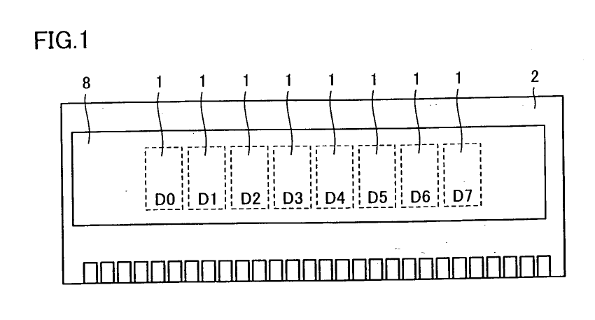

In the following, with reference to FIGS. 1 to 8, a semiconductor memory module of the embodiment of the present invention that is repairable after the bare chips are covered with a mold resin will be described.

The semiconductor memory module of the present embodiment is repaired, in the case that a bare chip is detected as being defective, by mounting a repair chip that can be substituted for this bare chip on the module substrate.

FIG. 1 shows a semiconductor memory module of the embodiment. As shown in FIG. 1, in the semiconductor memory module of the embodiment, a plurality of bare chips 1 are mounted directly on one of main surfaces of a module substrate 2 and the plurality of bare chips 1 are integrally molded into a mold resin 8.

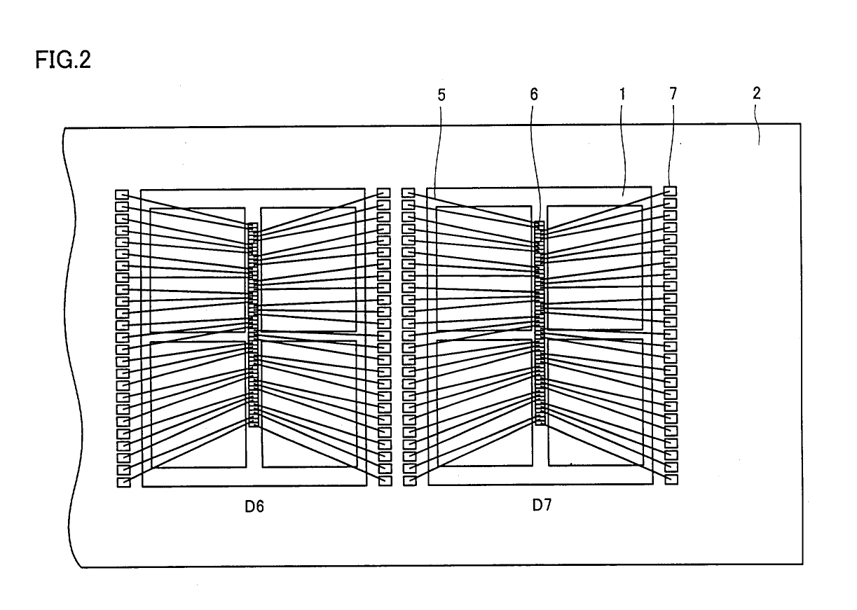

In addition, as shown in FIG. 2, chip bonding pads 6 provided on bare chips 1 and wiring pads 7 provided on module substrate 2 are connected by means of bonding wires 5.

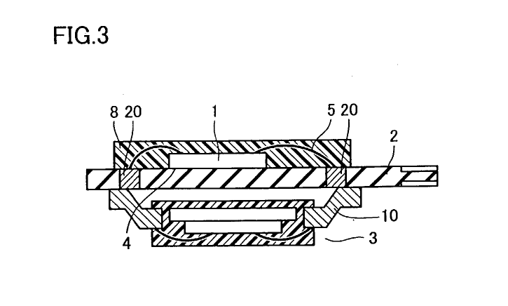

In addition, the semiconductor memory module of the embodiment has a structure wherein, in the case that any bare chip 1 from among the plurality of bare chips 1 is detected as being defective, a good chip 3 used in place of bare chip 1 can be mounted, as shown in FIG. 3, on the rear side of the main surface, on which the plurality of bare chips 1 are provided.

A bare chip 1 mounted on the front surface of semiconductor memory module substrate 2 and a good chip 3 as a repair chip mounted on the rear surface, which is used in place of this bare chip 1, utilize common electrical wires 20. In other words, in the case that good chips 3 are mounted, these electrical wires 20 are electrically connected, as shown in FIG. 3, to both the plurality of bare chips 1 mounted on the front surface and good chip 3 mounted in a region on the rear side where a plurality of good chips is expected to be mounted via through holes that penetrate module substrate 2.

In a manufacturing method for a semiconductor memory module of the present embodiment, as shown in FIG. 2, after a plurality of bare chips 1 are mounted on a module substrate 2, chip bonding pads 6 provided on bare chips 1 and wiring pads 7 provided on module substrate 2 are electrically connected by means of bonding wires 5. After that, as shown in FIG. 3, the plurality of bare chips 1 are integrally molded into a mold resin 8, thereby the semiconductor memory module is completed. Then, the semiconductor memory module has a structure wherein a molded good chip 3 can, if necessary, be mounted on the rear surface of module substrate 2 after the completion of the semiconductor memory module.

Here, FIG. 3 shows an example of a case that a single chip, wherein a single bare chip is covered with a mold resin, is used as good chip 3 that functions in place of bare chip 1. In the semiconductor memory module of the present embodiment, however, a bare chip is used as good chip 3. In addition, in the case that a bare chip is used as good chip 3, it becomes necessary to integrally cover the rear surface of module substrate 2, together with the bare chips, with a mold resin as described below.

In addition, the semiconductor memory module of the present embodiment has a structure that can be repaired by means of the mounting good chip 3 on the rear surface of module substrate 2 so that the functions of bare chip 1, which has become defective, are carried out by good chip 3 in the case that a defective product is detected from among the plurality of bare chips 1 by means of a variety of tests, such as a system test, after the manufacture of a memory module, which is an example of a semiconductor memory module.

Here, in order for good chip 3 to carry out the functions of bare chip 1, which has been detected as being defective, it is necessary to turn off the operation of bare chip 1, which has been detected as being defective. Therefore, it becomes necessary to control the condition wherein bare chip 1 functions and the condition wherein bare chip 1 does not function.

In the semiconductor memory module of the present embodiment, a signal of a predetermined potential is inputted to a terminal that is not utilized at the time of the actual utilization, thereby the ON/OFF switching of the input/output of bare chips 1 mounted on module substrate 2 is controlled so that good chip 3 carries out the functions of bare chip 1, which has been detected as being defective.

Here, the semiconductor memory module of the embodiment is integrally molded into mold resin 8 after the plurality of bare chips 1 are mounted on module substrate 2 and then, chip bonding pads 6 of bare chips 1 and wiring pads 7 on module substrate 2 are electrically connected. Therefore, the mounting area of the semiconductor memory module can be reduced.

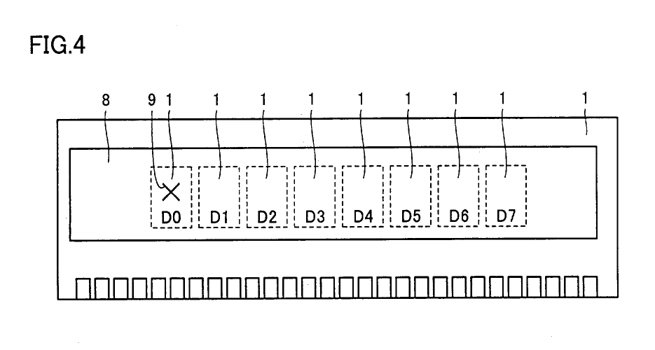

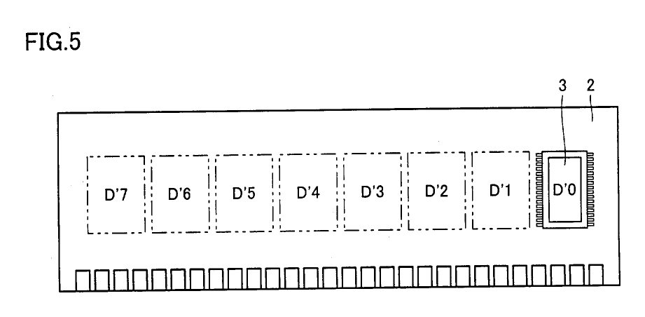

FIGS. 4 and 5 show a configuration example of a module substrate after repair. As shown in FIGS. 4 and 5, bare chips 1 (D0 to D7) are mounted on the front surface of module substrate 2 while a plurality of good chip mounting regions for good chip 3 (D′0 to D′7), mounted at the time of repair, is provided on the rear surface.

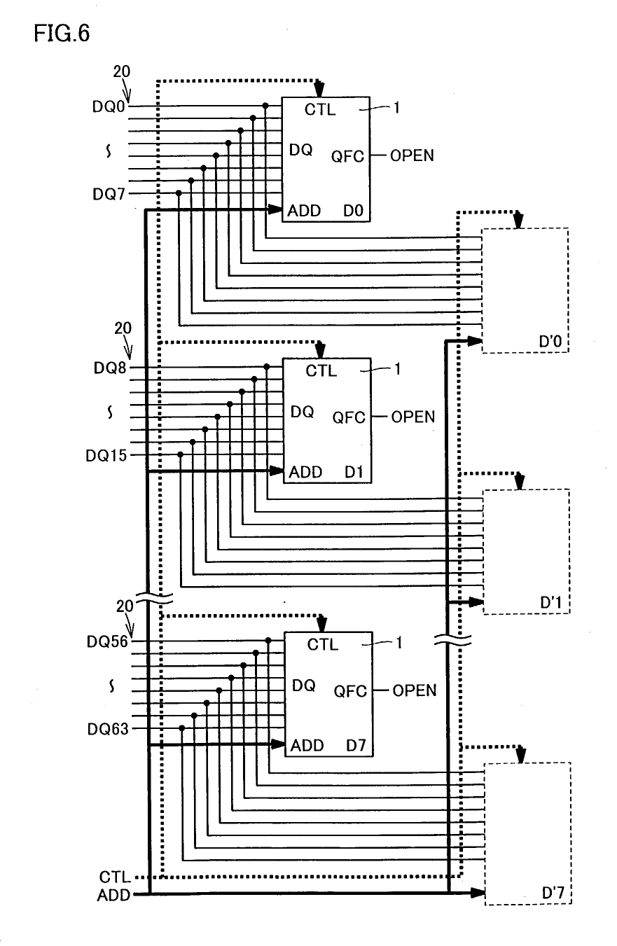

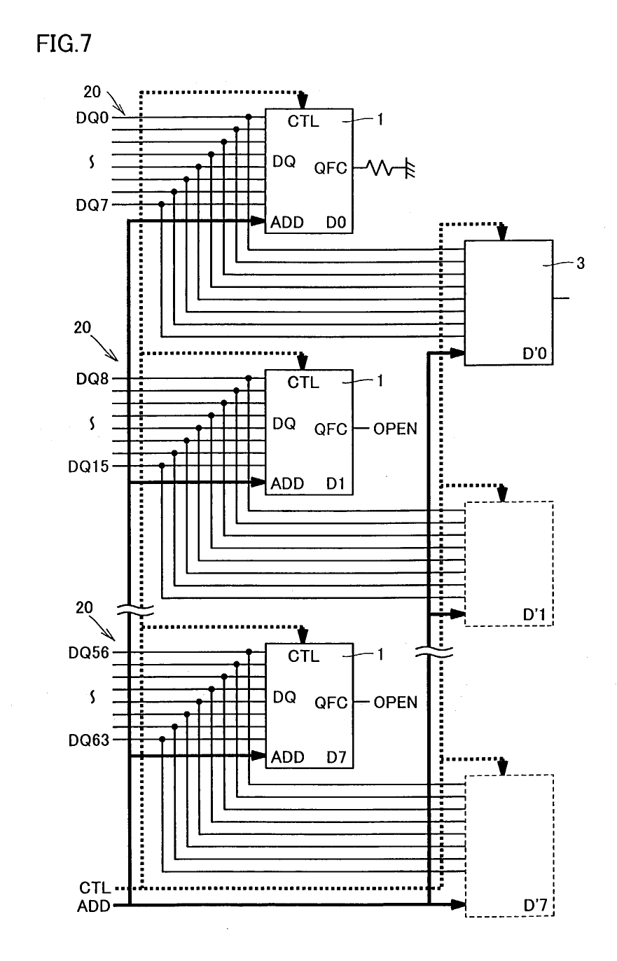

FIG. 6 shows a block diagram of the front and rear surfaces of module substrate 2 on which bare chips 1 (D0 to D7) are mounted before repair. As shown in FIG. 6, bare chips 1 (D0 to D7) are provided with QFC pins (not limited to only QFC pins as long as the terminals are not in normal use) for controlling the input/output of bare chip 1, which has been detected as being defective. FIG. 7 shows a block diagram of the front surface and of the rear surface of module substrate 2 on which good chips 3 (D′0 to D′7) utilized at the time of repair are mounted after repair. Here, bare chips 1 (D0 to D7) and good chips 3 (D′0 to D′7) utilize input/output terminals DQ0 to DQ63 connected to common electrical wires 20, respectively. Here, input/output terminals DQ0 to DQ63 are connected to other circuits or memories and are terminals for inputting/outputting electrical signals at these other circuits or memories.

Though the semiconductor memory module configuration before repair shown in FIG. 6 is not problematic because good chip 3 is not mounted, in the configuration of the semiconductor memory module after repair shown in FIG. 7, bare chip 1 (D0) and good chip 3 (D′0) utilize input/output terminals DQ0 to DQ63 that are connected to common electrical wires 20 and therefore, input/output signals of bare chip 1 (D0) and good chip 3 (D′0) collide each other, when both bare chip 1 (D0) and good chip 3 (D′0) are in operation.

Therefore, in the semiconductor memory module of the embodiment, the QFC pin of bare chip 1 detected as being defective is fixed at a predetermined potential so that the input/output of signals from the input/output terminals of this bare chip 1 is disabled, thereby the above described problem is prevented from occurring. Here, since the QFC pin has a structure that is exposed to the outside of mold resin 8, it is possible to fix the QFC pin at a predetermined potential from the outside even after bare chip 1 is covered with mold resin 8. In addition, the circuit configuration of the inside of bare chip 1 is a circuit configuration that does not carry out input/output of electrical signals from the input/output terminals of bare chip 1 when the potential of the QFC pin is fixed at the predetermined potential.

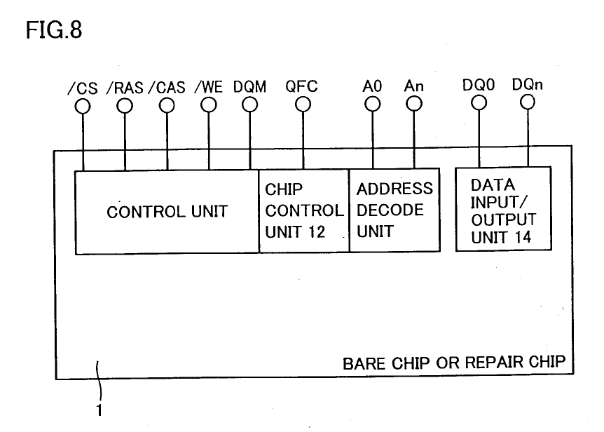

For example, as shown in FIG. 6, in the case that a QFC pin is in the OPEN condition, a bare chip 1 (D0 to D7) or a good chip 3 (D′0 to D′7) outputs electrical signals from an input/output unit 14 shown in FIG. 8 to input/output terminals DQ0 to DQ63 or inputs electrical signals from input/output terminals DQ0 to DQ63 to input/output unit 14 shown in FIG. 8 due to the operation of a chip control unit 12 shown in FIG. 8. In the case that a QFC pin is fixed at the ground potential (GND), a bare chip 1 (D0 to D7) or a good chip 3 (D′0 to D′7) stops the input of signals from input/output terminals DQ or the output of signals from input/output terminals DQ using input/output unit 14 shown in FIG. 8 due to the operation of chip control unit 12 shown in FIG. 8.

Accordingly, in the case that none of bare chips 1 have been detected as being defective, it is not necessary to mount a good chip 3 (D′O to D′7) and it becomes possible to implement a semiconductor memory module wherein a plurality of bare chips 1 is directly mounted on a module substrate 2. In addition, QFC pins not utilized at the time of the actual operation of the semiconductor device are normally controlled to be in the OPEN condition by means of chip control unit 12 in bare chips 1 (D0 to D7) at the time of operation of the semiconductor device so that the output of signals from bare chip 1 (D0 to D7) to input/output terminals DQ0 to DQ63 is carried out or the input of signals from input/output terminals DQ0 to DQ63 to bare chip 1 (DQ) is carried out.

Furthermore, in the semiconductor memory module, in the case that a bare chip 1 is detected as being defective from among bare chips 1 (D0 to D7), a good chip (good chips) 3 (D′0 to D′7) is (are) mounted on the rear surface opposite to the surface of module substrate 2 on which bare chips 1 are provided and the QFC pin of bare chip(s) 1 (D0) is (are) fixed at the ground potential (GND), thereby bare chip(s) 1 (D0) stop(s) the output of signals to input/output terminals DQ0 to DQ7 and the input of signals from input/output terminals DQ0 to DQ7. Thereby, good chip 3 (D′0) outputs electrical signals to input/output terminals DQ0 to DQ7 or electrical signals are inputted from input/output terminals DQ0 to DQ7. Accordingly, the functions of defective bare chip 1 are taken over (replaced) by good chip 3 so that the semiconductor memory module can be repaired.

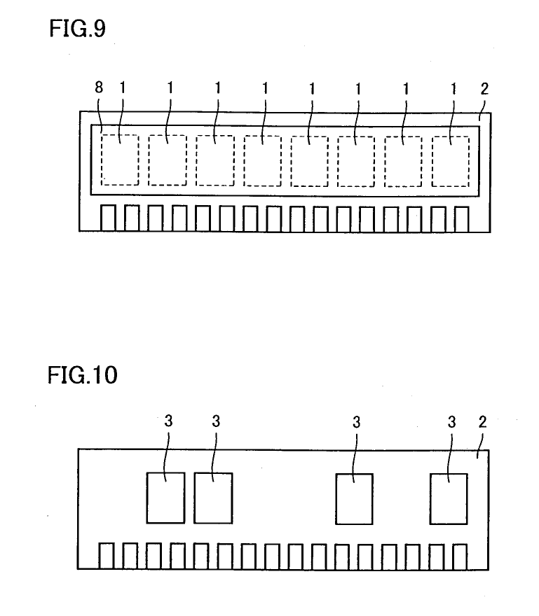

Next, with reference to FIGS. 9 and 10, a semiconductor memory module that has been repaired after the completion of the system test will be described. As shown in FIGS. 9 and 10, a good chip (good chips) 3 is (are) provided only in a position corresponding to the position of bare chip(s) 1, which has been detected as being defective, on the rear surface of module substrate 2 after the completion of the system test.

Here, though FIG. 3 shows an example of the use of a single mold product, wherein a single bare chip is molded, as good chip 3, FIGS. 10 to 14 in the following show examples wherein a bare chip is used as good chip 3 in a semiconductor memory module.

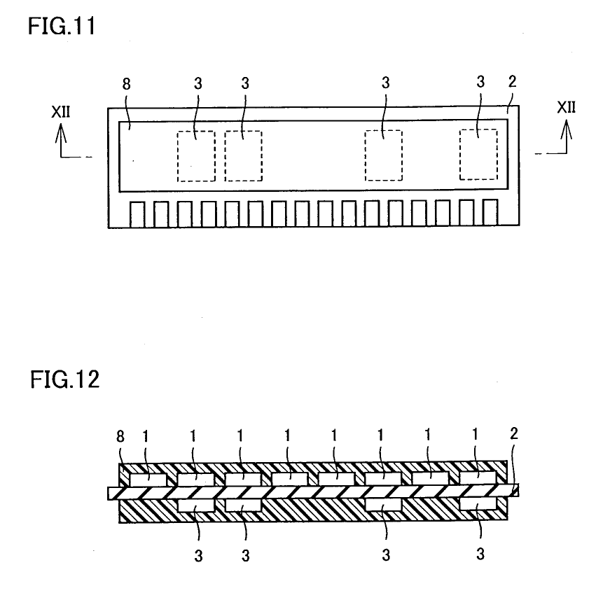

In addition, in a semiconductor memory module under the conditions shown in FIG. 10, good chips 3 are supposed to be mounted in all of the good chip mounting regions for mounting good chips 3, as shown in FIGS. 11 and 12, regardless of whether or not they are the regions wherein a good chip 3 is provided, and then almost the entirety of the rear surface of module substrate 2 is integrally molded into mold resin 8 so as to cover all of the supposed good chips 3.

It is to prevent disadvantage that occurs as a result of irregularities in the external forms, respectively, of the plurality of semiconductor memory modules when good chips are mounted on module substrates only at positions corresponding to bare chips that have been detected as being defective in the case that the semiconductor memory modules are repaired by mounting good chips on module substrates as described above. That is to say, a bare chip that becomes defective differs for every semiconductor memory module and therefore, the disadvantage occurs wherein a position where a good chip is mounted on a module substrate differs for every semiconductor memory module and the above measure is implemented in order to prevent this disadvantage.

In more concrete terms, in the case that the rear surface of module substrate 2 is not integrally covered, it becomes difficult to pack a plurality of semiconductor memory modules in a box for transport in a well-organized manner at the time of transport of the semiconductor memory modules. That is to say, gaps are formed between the semiconductor memory modules in the box in which semiconductor memory modules are packed. As a result, semiconductor memory modules collide with each other in a box during transport of semiconductor memory modules. Thereby, semiconductor memory modules are damaged.

Then, as shown in FIGS. 11 and 12, all of good chips 3 for repair are supposed to be mounted, regardless of whether or not good chip 3 for repair is mounted and the entirety of the rear surface of module substrate 2 is integrally molded so as to cover all of the supposed good chips. Thereby, the external form of the mold resin in the vicinity of good chip mounting regions can be in a form wherein gaps do not easily occur between semiconductor memory modules at the time when semiconductor memory modules are packed. As a result, damage to the semiconductor memory modules due to collision of the semiconductor memory modules can be prevented from occurring at the when the semiconductor memory modules are transported in packaging.

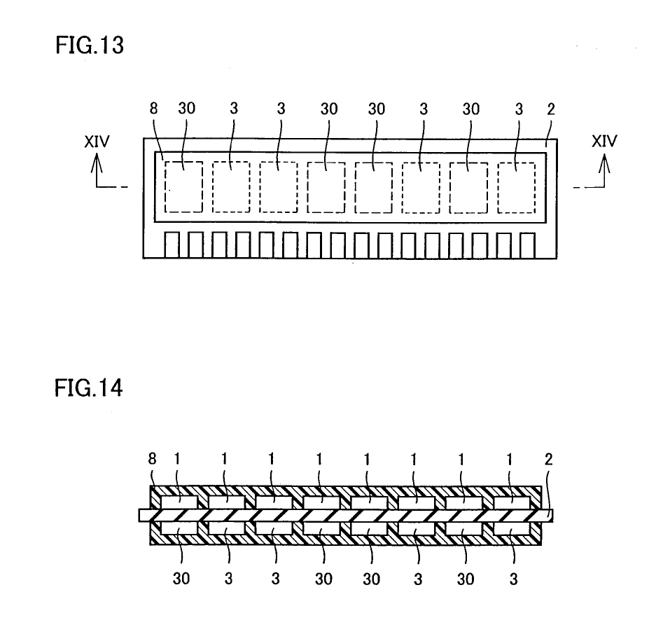

In addition, in the above described semiconductor memory module after repair shown in FIGS. 11 and 12, nothing other than mold resin 8 is mounted in the good chip mounting regions for mounting good chips 3 on module substrate 2 where repair chips are not utilized. As shown in FIGS. 13 and 14, however, it is desirable to mount dummy chips 30 in the good chip mounting regions on which good chips 3 are not mounted. Single mold products (single chips) of which bare chips are not sealed inside, single defective mold products which are single mold products and in which defective portions have been detected, and pieces that are simply cut out of substrates so as to have the same form and size as that of mold products and that do not function as good chips, may be considered as such dummy chips 30. In addition, it is preferable for dummy chips 30 to have the same form and size as of bare chips 1 and good chips 3, respectively.

According to such a semiconductor memory module of the present embodiment, dummy chips 30 are provided, thereby it becomes easy to make the external form of mold resin 8 over module substrate 2 on which good chip 3 is not mounted approximately the same as the external form of mold resin 8 over module substrate 2 on which good chip 3 is mounted. Therefore, the external form of a semiconductor memory module can be made to have a form wherein gaps do not easily occur between a plurality of semiconductor memory modules at the time of transport when the semiconductor memory modules are packed in a box. As a result, according to a semiconductor memory module of the present embodiment, it becomes possible to prevent semiconductor memory modules from being damaged during transport.

In addition, since dummy chips 30 and good chips 3 have the same forms and sizes, it is easy to make the external form of mold resin 8 into a form wherein gaps do not easily occur between a plurality of semiconductor memory modules.

Here, though an example wherein dummy chips 30 are mounted on all of the regions on which good chips 3 can be mounted is shown in the semiconductor memory module of the present embodiment, a good chip may be mounted on any one region from among a plurality of good chip mounting regions on which good chips 3 can be mounted or on two or more regions selected from among a plurality of good chip mounting regions on which good chips 3 can be mounted instead of mounting dummy chips 30 on all of the regions on which good chips 3 can be mounted. In the case that at least one dummy chip 30 exists, it becomes easy to make the external form of the semiconductor memory module into a form wherein gaps do not easily occur between a plurality of semiconductor memory modules.

(Second Embodiment)

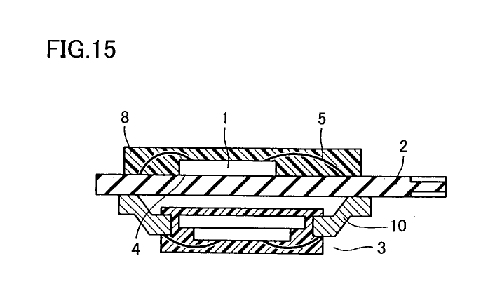

Next, with reference to FIGS. 15 to 20, a semiconductor device of the present embodiment will be described.

Though the semiconductor memory module of the present embodiment has approximately the same structure as the semiconductor memory module of the first embodiment, as shown in FIGS. 15 to 17, the semiconductor memory module of the present embodiment differs from the semiconductor memory module described in the first embodiment in the point that a plurality of electrical wires 20 formed in a module substrate 2 in the structure shown in FIG. 3 does not electrically connect a bare chip 1 and a good chip 3 by penetrating module substrate 2 in the present embodiment.

That is to say, a good chip 3 of the present embodiment is provided with electrical wires 20 which are separated and independent of a bare chip 1, and with input/output terminals DQ0 to DQ63, respectively, connected to these electrical wires 20. Therefore, it is possible for good chip 3 of the present embodiment to serve as a memory in place of any bare chip 1 from among a plurality of bare chips 1 or a plurality of bare chips 1 combined from among the plurality of bare chips after the plurality of bare chips 1 are molded into a mold resin 8, and at the same time, it is also possible to serve as a memory in order to change or increase the capacity of the semiconductor memory module. Here, in the semiconductor memory module of the present embodiment, bare chips may be used as good chips 3 for repair as shown in FIGS. 19 and 20 or single chips may be used as shown in FIG. 15.

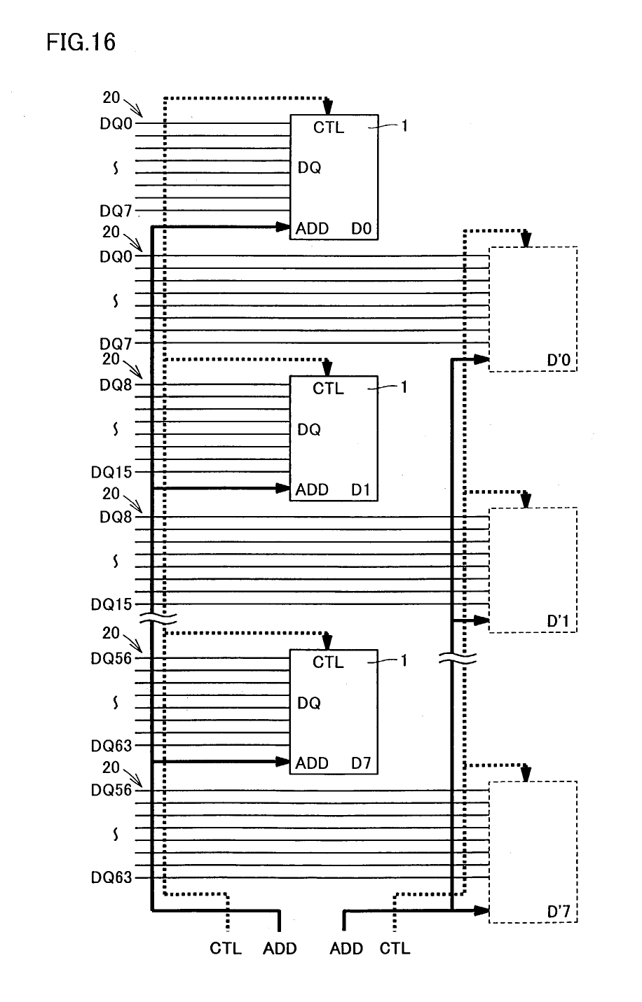

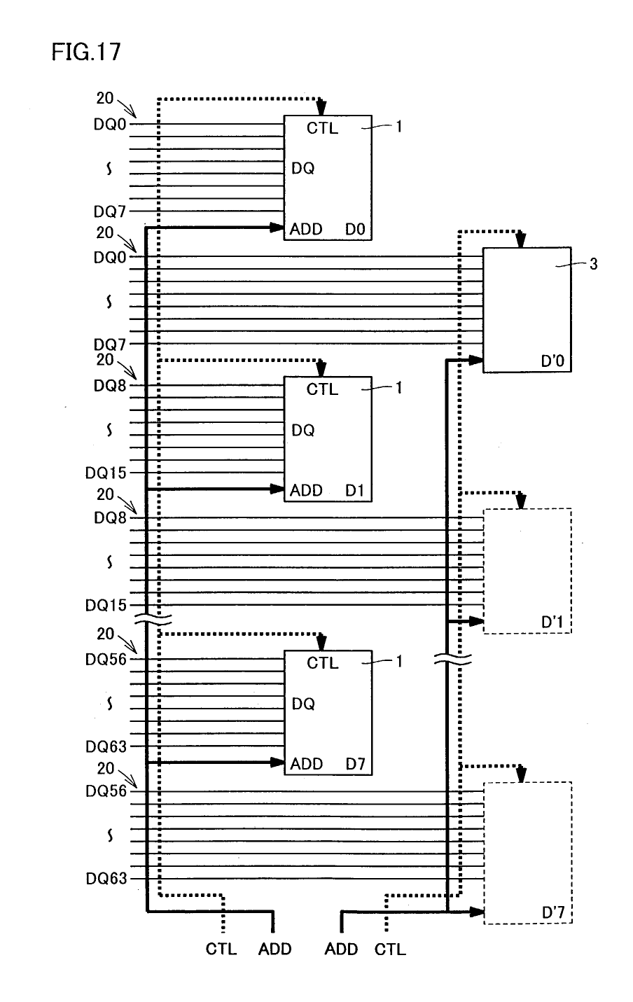

In further detail, the semiconductor memory module of the present embodiment differs from semiconductor memory module of the first embodiment, as shown in FIGS. 16 and 17, in the point that electrical wires 20 are independently connected to bare chips 1 and to good chips 3, respectively, and these independent electrical wires 20 are connected to different input/output terminals DQ0 to DQ63, respectively, in the present embodiment. Conversely, the semiconductor memory module of the present embodiment has the same structure as of the semiconductor memory module of the first embodiment in regard to the structures shown in FIGS. 1, 2, 4 and 5.

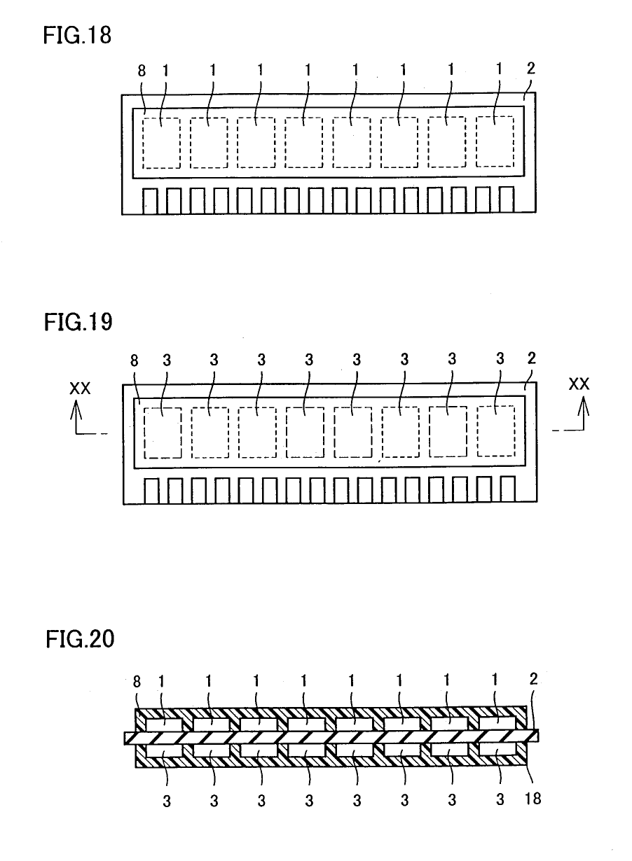

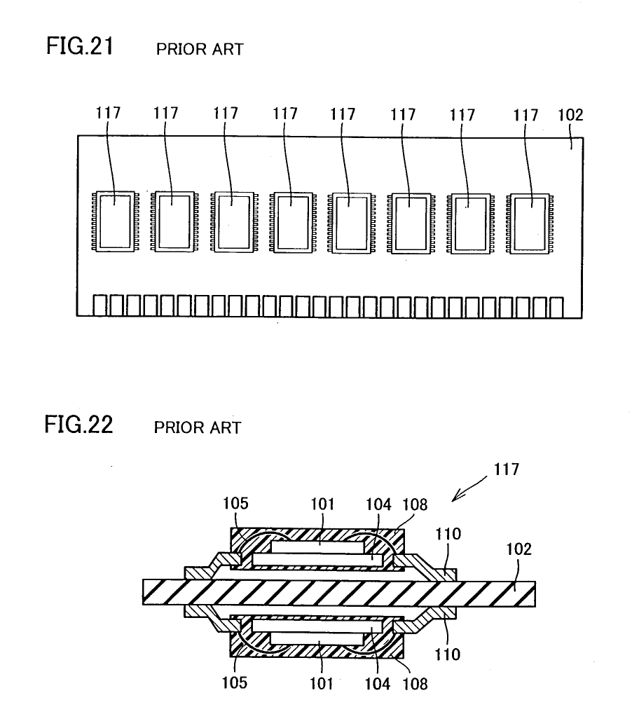

In addition, in the semiconductor memory module of the present embodiment, as shown in FIGS. 18 to 20, good chips 3 of the same number as of bare chips 1 are mounted on the rear surface of module substrate 2. Accordingly, the semiconductor memory module of the present embodiment has a memory capacity two times greater than the semiconductor memory module wherein a plurality of bare chips 1 are mounted on module substrate 2.

For example, in the semiconductor memory module of the present embodiment, one bare chip 1 has a memory capacity of 8 MB and, in the case that eight bare chips 1 forming a total memory capacity of 64 MB are mounted on the surface of module substrate 2, the total memory capacity thereof becomes 64 MB. Furthermore, eight single good chips 3, of 8 MB each, are mounted on the rear surface of module substrate 2 of the semiconductor memory module, thereby the semiconductor memory module of the present embodiment has a total memory capacity of 128 MB at the time of completion to have a memory capacity two times as large as the memory capacity at the point in time when eight bare chips 1 are mounted on the surface.

In addition, the semiconductor memory module of the present embodiment is manufactured through the following manufacturing process. First, a plurality of bare chips 1 of 64 MB is integrally molded into a mold resin 8 on the surface through the same manufacturing process as the manufacturing method for a semiconductor device described in the first embodiment. Next, in the case that a module of 128 MB is manufactured, once a system test is carried out. According to the result of the system test, eight good chips 3 of 64 MB are mounted only on the rear surface of module substrate 2 of a semiconductor memory module wherein all bare chips 1 on the surface of module substrate 2 are detected as being good products so that a semiconductor memory module of 128 MB is manufactured. Next, the plurality of good chips 3 are integrally covered with a mold resin 18 together with the rear surface of module substrate 2.

The following effects are obtained by mounting eight good chips 3 of 64 MB only on the rear surface of module substrate 2 of a semiconductor memory module wherein all bare chips 1 on the surface of module substrate 2 are detected as being good products according to the results of the system test, as in the above described manufacturing method.

According to the manufacturing method for a semiconductor memory module of the present embodiment, in the case that a defect is detected from among bare chips 1 mounted on the surface of module substrate 2 as a result of a system test so that a semiconductor memory module of 128 MB cannot be manufactured because one of bare chips 1 on the front surface side of module substrate 2 is defective, it becomes possible to obtain a good product of a module of 64 MB by mounting a good molded product only in place of the defective portion.

As a result, in the case that a bare chip 1 is detected as being defective by means of a system test, a good chip 3 is mounted on module substrate 2 in place of the defective bare chip 1, thereby the semiconductor memory module can be repaired after the plurality of bare chips 1 are covered with mold resin 8 in the same manner as the semiconductor memory module of the first embodiment.

Thereby, in the case that a portion of the integrally covered plurality of bare chips 1 are a defective bare chip so that the remaining good portion of bare chips 1 is expected to be disposed of, a semiconductor memory module can be manufactured by effectively utilizing the good portion of bare chips 1.

In addition, in the case that it has become necessary to change or increase the memory capacity of the entirety of the semiconductor memory module after the system test regardless of whether or not a bare chip 1 is detected as being defective, a necessary number of good chips 3 may be mounted on module substrate 2. Thereby, it becomes possible to quickly make a design change of the memory capacity of the semiconductor memory module, even after the plurality of bare chips 1 are molded into mold resin 8.

(Third Embodiment)

Next, a semiconductor memory module of the present embodiment will be described with reference to FIGS. 15 to 20.

Though the semiconductor memory module of the present embodiment has approximately the same structure as the semiconductor memory module of the first embodiment, as shown in FIGS. 15 to 17, the semiconductor memory module of the present embodiment differs from the semiconductor memory module described in the first embodiment in the point that a plurality of electrical wires 20 formed in module substrate 2 according to the structure shown in FIG. 3 does not electrically connect a bare chip 1 and a good chip 3 by penetrating through module substrate 2; in the same manner as of the semiconductor memory module described in the second embodiment.

In other words, the semiconductor memory module of the present embodiment differs from the semiconductor memory module of the first embodiment in the point that electrical wires 20, shown in FIGS. 6 and 7, are independently connected to bare chips 1 and good chips 3, respectively, so that these independent electrical wires 20 are connected to different input/output terminals DQ, respectively, in the present embodiment. Conversely, the semiconductor memory module of the present embodiment has the same structure as that of the first embodiment in regard to the structures shown in FIGS. 1, 2, 4 and 5.

In addition, the semiconductor memory module of the present embodiment is manufactured through the following manufacturing process. First, a plurality of bare chips 1 on the surface are integrally molded into a mold resin 8 through the same manufacturing process as of the manufacturing method for a semiconductor device described in the first embodiment. After that, a system test is carried out on the semiconductor memory module wherein the plurality of bare chips 1 is mounted on the surface of module substrate 2. In the case that all bare chips 1 mounted on the surface of module substrate 2 are good products at the stage when this system test is completed, as shown in FIGS. 18 to 20, mountable good chips 3 making up a plurality are all mounted on the rear surface of module substrate 2 so as to correspond to bare chips 1, respectively. Next, the entirety of the plurality of good chips 3 are integrally covered with a mold resin 18 together with the rear surface of module substrate 2.

After that, a system test is carried out on the semiconductor memory module wherein the plurality of good chips 3 are mounted on the rear surface of module substrate 2. In the case that a defect is detected from among good chips 3 by means of this system test, the electrical connections between the plurality of good chips 3 and other circuits, respectively, are blocked or the plurality of good chips 3 is put into an inactive condition, respectively.

In the case that eight bare chips 1 mounted on the surface of module substrate 2 are all detected as being good products by means of the system test in, for example, the semiconductor memory module of 128 MB, which is an example described in the second embodiment, eight good chips 3 are mounted on the rear surface of module substrate 2. After that, an additional system test is carried out on the semiconductor memory module on which good chips 3 are mounted. In the case that a defective product is detected from among eight good chips 3 as a result of this system test, electrical connections between respective good chips 3 and other circuits are blocked or good chips 3 are inactivated, respectively.

Thereby, it becomes possible to utilize the semiconductor memory module wherein the electrical connections between the eight good chips 3, respectively, and the other circuits are blocked as a good semiconductor memory module in a condition wherein only the eight bare chips 1 mounted on the surface of module substrate 2 function.

Here, in the manufacturing method for a semiconductor memory module of the present embodiment, the surface of module substrate 2 is integrally covered together with good chips 3 after respective good chips 3 are blocked from other circuits or respective good chips 3 are inactivated.

According to the above described manufacturing method for a semiconductor memory module, in the case that, a defective chip is detected from among this mounted plurality of good chips 3 after a plurality of good chips 3 is mounted, the entirety of the functions of the plurality of good chips 3 are disabled, that is to say, the plurality of good chips 3, respectively, is blocked from other circuits or the plurality of good chips 3 are, respectively, inactivated, thereby a semiconductor memory module wherein the functions of bare chips 1 only are effectively utilized.

In addition, though in the above description the connections between the entirety of the plurality of good chips 3 and other circuits are blocked or the entirety of the plurality of good chips 3 is inactivated, in accordance with the results of the test for detecting whether or not there is any defect from among good chips 3, one or plural particular good chips 3 only from among the plurality of bare chips 3 may be blocked from other circuits or may be inactivated. According to such a manufacturing method, it becomes possible to change or to increase the memory capacity of the semiconductor memory module after a test for detecting whether or not there is any defect from among good chips 3.

In addition, single chips shown in FIG. 15 or bare chips shown in FIGS. 19 and 20, may also be used as good chips 3 for repair in the semiconductor memory module of the present embodiment in the same manner as in the semiconductor memory modules of the first and second embodiments.

Here, though in the semiconductor memory modules of the present first to third embodiments, examples are shown wherein bare chips 1 are mounted on one (front surface) of the surfaces of module substrate 2 while good chips 3 are mounted on the other surface (rear surface), both bare chips and good chips are mounted on only one surface of a module substrate while no chips are mounted on the other surface in the case that a large module substrate can be used.

In addition, it is possible to combine the characteristics of the semiconductor memory modules and the manufacturing methods for the same of the above described first to third embodiments depending on conditions.

Although the present invention has been described in detail, it is clearly understood that the same is by way of illustration and example only and is not to be taken by way of limitation, the spirit and scope of the present invention being limited only by the terms of the appended claims.

What is claimed is:

1. A semiconductor memory module, comprising:
a module substrate;
a plurality of bare chips mounted on a main surface of the module substrate;
one mold resin for integrally covering said plurality of bare chips together with the main surface of said module substrate;
a plurality of good chip mounting regions that are regions on the main surface of said module substrate, wherein in the case that any one or plural bare chips among said plurality of bare chips are detected as being defective, one or plural good chips, which function in place of said one or plural bare chips that have been detected as being defective, can be mounted, and
another mold resin for integrally covering, in the case that all of said good chips that can be mounted in said plurality of good chip mounting regions are supposed to be mounted regardless of whether or not said one or plural good chips are mounted in the plurality of good chip mounting regions, the entirety of said plurality of good chip mounting regions together with the entirety of the supposed good chips.

2. The semiconductor memory module according to claim 1, wherein
one dummy chip that has approximately same form and same size as that of said bare chip and that does not function as said good chip is mounted in one region among said plurality of good chip mounting regions.

3. The semiconductor memory module according to claim 1, wherein
dummy chips having approximately the same form and the same size as that of said bare chips and not functioning as said good chip are mounted in said plurality of good chip mounting regions, respectively.

4. A semiconductor memory module, comprising:
a module substrate;
a plurality of bare chips mounted on a main surface of the module substrate and including one or plural defective bare chips that do not function properly;
a mold resin for integrally covering said plurality of bare chips together with the main surface of said module substrate; and
one or plural memory chips mounted on the main surface of said module substrate outside of the mold resin that function independently of said plurality of bare chips, respectively.

5. The semiconductor memory module according to claim 4, wherein
said one or plural memory chips are used as repair chips that function in place of said defective bare chips.

6. The semiconductor memory module according to claim 4, wherein
said one or plural memory chips are used as chips that change the memory capacity of the entirety of the semiconductor memory module.

7. A semiconductor memory module, comprising:
a module substrate;
a plurality of bare chips mounted on a main surface of the module substrate;
a mold resin for integrally covering said plurality of bare chips together with the main surface of said module substrate; and
one or plural memory chips mounted on the main surface of said module substrate that function independently of said plurality of bare chips, wherein
the function of at least one memory chip of said one or plural memory chips is disabled.

8. The semiconductor memory module according to claim 7, wherein
the functions of the entirety of said one or plural memory chips are disabled.
